(19) United States
(12) Patent Application Publication
(10) Pub. No.: US 2009/0059491 A1
(43) Pub. Date: Mar. 5, 2009

(54) Portable electronic device

(75) Inventors: Pekka Pihlaja, Helsinki (FI); Mikko AArras, Helsinki (FI)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(73) Assignee: NOKIA CORPORATION, Espoo (FI)

(21) Appl. No.: 12/290,210

(22) Filed: Oct. 27, 2008

Related U.S. Application Data
(62) Division of application No. 10/940,592, filed on Sep. 13, 2004.

(51) Int. Cl. H05K 5/00

(52) U.S. Cl. 361/679.56

(57) ABSTRACT

Multiple body element portable electronic devices are configurable to predetermined fixed orientations each of which define a respective different operative position wherein one body element is arranged to move relative to another body element from an overlapping closed operative position to a non-overlapping operative position to maximize the surface area relative to usage of each body element. The multiple body elements may be arranged for slidable, hinged and swivel movement with respect to one another.

### CROSS REFERENCE TO RELATED APPLICATIONS

This application is a divisional of U.S. patent application Ser. No. 10/940,592 filed Sep. 13, 2004, from which priority is claimed under all applicable sections of Title 35 of the United States Code including, but not limited to, Sections 121 and 365(c), and the entire contents of which are incorporated herein by reference.

### BACKGROUND

1. Field of the Invention

The present invention relates generally to electronic devices, particularly portable electronic devices and more specifically to portable electronic devices having multiple body elements configurable to predetermined fixed orientations each of which define a respective different operative position.

2. Description of Related Art

The demand by users and the purchasing public that portable electronic devices, particularly mobile telephone devices, become increasing smaller and lighter while at the same time providing an increasing number of different functions in addition to the basic telephone communication functions places a premium on available surface space for the user interfaces necessary to carryout the intended functions and operations of the associated features. In addition, there is also a demand for larger size screens for displaying images, for example, taken with a camera built into the mobile telephone or for displaying received images such as streaming video. This demand has required the manufacturer of such devices to design and develop innovative device enclosures capable of reconfiguration from one operative position to another to provide the necessary user interface to operate the device and to accommodate larger size screens. One such mobile telephone device enclosure is the “flip” phone wherein the cover of the device is hinged to a main body element which carries a user interface relative to usage and the cover is “flipped” to open the device to make the user interface assessable to the user. The inside surface of the cover carries a screen to display alphanumeric characters, graphics, images and other representations common to such mobile telephone devices and which are commonly known in the trade and by the consuming public. The “flip” phone enclosure configuration provides one method to expand the user interface surface and provide a larger screen display area while maintaining a relatively smaller size device enclosure compared to other mobile telephone devices wherein the user interface and the screen share a common surface area.

Another mobile telephone device enclosure as illustrated, for example, in FIGS. 1A-1C is the “slide” phone generally designated 10 wherein the cover 12 overlays a main body element 14 and is arranged for sliding engagement with the main body element 14. The cover 12 carries a screen 16 and may include keys 18 to carry out various intended functions of the device when the cover 12 is in its overlying operative position as shown in FIG. 1A. The device is configured to a second operative position when the cover 12 is slid by a user in the direction shown by arrow 20 to expose a surface 22 of the main body element 14 as shown in FIG. 1B wherein the surface 22 carries a user interface 24 which may be an arrangement of keys 26 in a desired pattern to carry out the intended function such as inputting a telephone number or entry of alphanumeric characters to the device in a well known manner. The device is returned to its closed operative position by sliding the cover 12 in the direction shown by the arrow 21. Although such “slide” phones provide ease of usage in changing from one operative position to another operative position, the increase in effective user interface area provided by “slide” phones is not as effective as “flip” phones because of the limited movement of the cover 12 with respect to the main body element 14. As schematically illustrated in FIG. 1C, an overlap of the cover 12 and main body element 14 represented by the length 28 is typically a 50 percent overlap and results in a hidden area 30 between the cover 12 and main body element 14 to maintain rigidity of the “slide” phone in its extended open position and thus the hidden area 30 of the main body element surface 22 is not available for usage as a user interface or for any other function.

What is needed therefore is a portable electronic device wherein one body element is arranged to move relative to another body element from an overlapping closed operative position to a non-over lapping operative position to maximize the surface area relative to usage of each body element.

It is also desirable to provide a portable electronic device wherein one body element is arranged to move relative to another body element to maximize the surface area relative to usage of each body element for use as a user interface.

It is also desirable to provide a portable electronic device wherein one body element is arranged for relative movement with respect to another body element to configure the body elements in a number of different predetermined fixed orientations each of which define a different operative position.

### SUMMARY

In accordance with a broad aspect of the invention, a device is presented and has a first main body element having a first major surface relative to usage and a second body element having a first major surface relative to usage. An arm mechanism is sandwiched between the first main body element and the second body element and is arranged to mechanically couple the first main body element to the second body element for relative movement with respect to one another. The first main body element is arranged for movement in a first plane and the second body element is arranged for movement in a second plane parallel with the first plane, to configure the first main body element and the second body element relative to one another in a number of different predetermined fixed orientations, each of the predetermined fixed orientations defining a corresponding different operative position of the device

In some embodiments of the invention, the device is arranged in a first operative position wherein the first main body element and the second body element are in an overlying stacked relationship with one another and the second body element first major surface is exposed and accessible by a user and the first main body element first major surface is covered by the second body element. In some embodiments of the invention, the device is arranged in a second operative position wherein the second body element moves relative to the first main body element along a first arcuate path in a first direction from its overlying stacked relationship with the first main body element to a fully open orientation to uncover the first main body element first major surface for access by a user. In some embodiments of the invention, the device is arranged in a third operative position wherein the second body element moves relative to the first main body element along a second arcuate path in a second direction opposite the direction from its overlying stacked relationship with the first main body element to a lengthwise extended orientation to uncover a portion of the first main body element first major surface for access by a user.

In some embodiments of the invention, a user interface is constructed in the first main body element first major surface. In some embodiments of the invention, the user interface comprises an arrangement of keys. In some embodiments of the invention, the arrangement of keys is a QWERTY keyboard. In some embodiments of the invention, the user interface is a user input device. In some embodiments of the invention, a display is constructed in the second body element first major surface. In some embodiments of the invention, the arm mechanism further comprises a pair of arms sandwiched between the first main body element and the second body element. In some embodiments of the invention, the arm mechanism further comprises a pair of swivel arms sandwiched between the first main body element and the second body element. In some embodiments of the invention, the device is a mobile telephone.

In another broad aspect of the invention, a device is presented and has a first main body element having a first major surface relative to usage and a second body element having a first major surface relative to usage. The device also has means for mechanically coupling the first main body element to the second body element, wherein the second body element is arranged for relative movement with respect to the first main body element to configure the first main body element and the second body element in a number of different predetermined fixed orientations, each of the predetermined fixed orientations defining a corresponding different operative position

### BRIEF DESCRIPTION OF THE DRAWINGS

Additional features, objects and advantages of the present invention will become readily apparent from the following written description taken in conjunction with the drawings wherein:

FIG. 1A is a top plan view of a slide mobile telephone in its closed operative position;

FIG. 1B is a top plan view of the slide mobile telephone of FIG. 1A in its open operative position;

FIG. 1C is a schematic side view of the mobile telephone of FIG. 1B illustrating the overlapping area between the cover and main body element.

FIG. 2A is a schematic perspective view of a first embodiment of the present invention showing a mobile telephone in a first operative position;

FIG. 2B shows the mobile telephone of FIG. 2A in a second operative position;

FIG. 2C shows the mobile telephone of FIG. 2A in a third operative position;

FIG. 2D is a rear schematic perspective view of the mobile telephone shown in FIG. 2C;

FIG. 3A is a schematic perspective view of a second embodiment of the present invention showing a mobile telephone in a first operative position;

FIG. 3B is a schematic side view of the mobile telephone shown in FIG. 3A;

FIG. 3C shows the mobile telephone of FIG. 3A in a fully open second operative position;

FIG. 3D is a schematic side view of the mobile telephone shown in FIG. 3C;

FIGS. 4A-4I illustrate schematically a third embodiment of the present invention showing a mobile telephone having a sliding mechanism sandwiched between the first main body element and the second body element whereby the mobile telephone has a closed operative position (FIG. 4A), a vertically open operative position (FIG. 4D) and a horizontally open operative position (FIG. 4G).

FIGS. 5A-5H illustrate schematically a fourth embodiment of the present invention showing a mobile telephone having a sliding mechanism sandwiched between the first main body element and the second body element whereby the mobile telephone has a closed operative position (FIG. 5A), a first vertically open operative position in a first direction (FIG. 5E) and a second vertically open operative position in a second direction (FIG. 5G) opposite the first direction;

FIGS. 6A-6E illustrate schematically a fifth embodiment of the present invention showing a mobile telephone having a foldable hinge frame sandwiched between the first main body element and the second body element whereby the mobile telephone has a vertical operative position (FIG. 6B) and a horizontal operative position (FIG. 6C);

FIGS. 7A-7D illustrate schematically a sixth embodiment of the present invention showing a mobile telephone having a pair of swivel arms sandwiched between the first main body element and the second body element whereby the mobile telephone has an open horizontal operative position (FIG. 7C) and an open vertical operative position (FIG. 7D);

FIGS. 8A-8D illustrate schematically a seventh embodiment of the present invention showing a mobile telephone having a pair of swivel plates sandwiched between the first main body element and the second body element whereby the mobile telephone has a closed operative position (FIG. 8A) and an open horizontal operative position (FIG. 8D).

FIGS. 9A-9F illustrate schematically an eighth embodiment of the present invention showing a mobile telephone having a single swivel arm sandwiched between the first main body element and the second body element whereby the mobile telephone has a closed operative position (FIG. 9A), an open vertical operative position revealing a first user interface area carried by the swivel arm (FIG. 9E) and a horizontal operative position revealing a second user interface area carried on the first main body element and the first user interface area carried on the swivel arm (FIG. 9F).

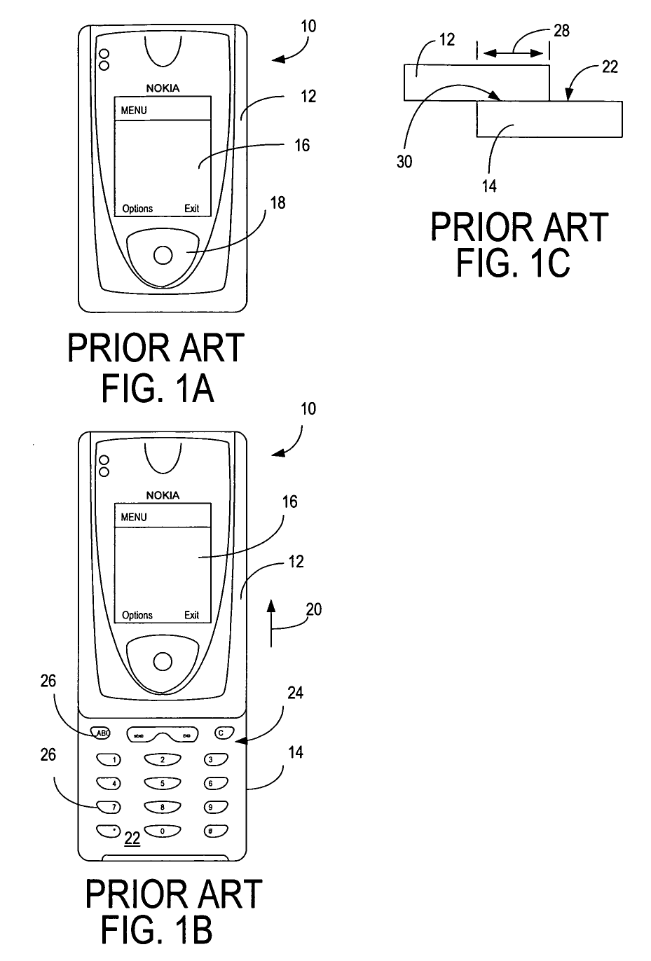

### DETAILED DESCRIPTION

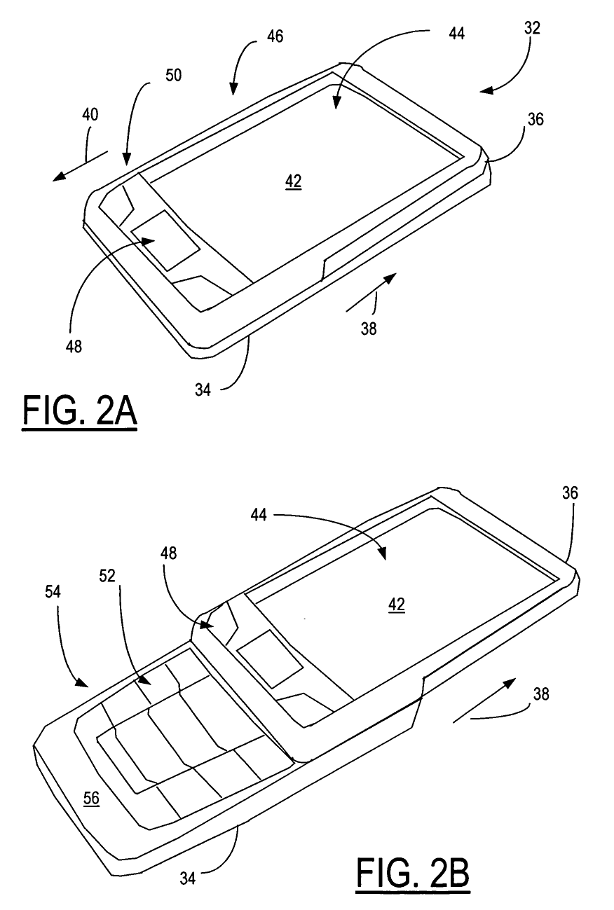

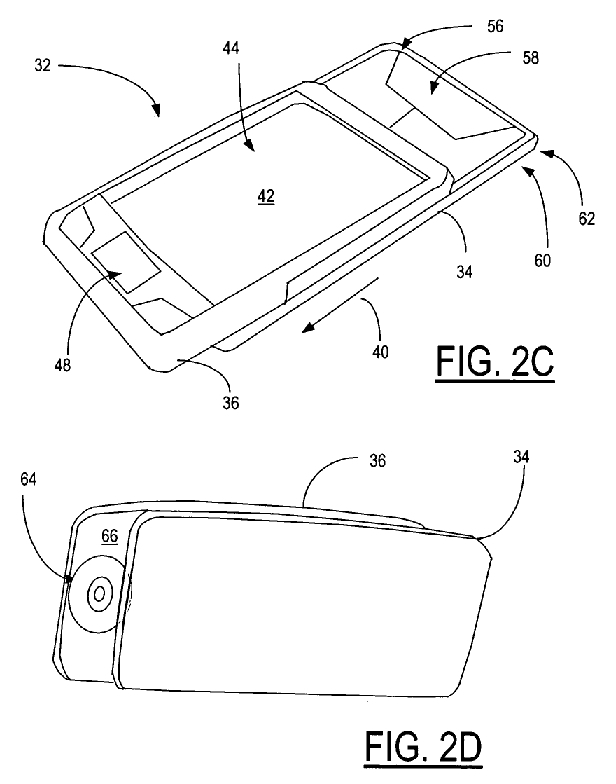

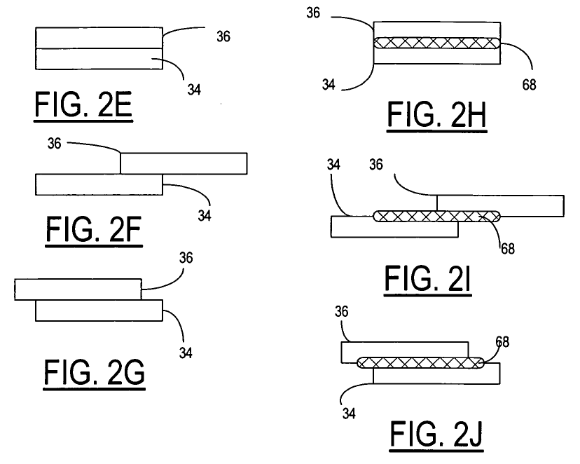

Turning now to the drawings and considering the invention in further detail, a schematic perspective view of a first embodiment of the portable electronic device of the present invention is illustrated schematically in FIGS. 2A-2D and shows for purposes of explanation of the invention a mobile telephone generally designated 32 in FIG. 2A in a first or closed operative position. As shown in FIG. 2A, the mobile phone 32 includes a first main body element 34 and a stacked or overlying second body element generally designated 36 arranged for relative movement with respect to the main body element 34 along a linear path in a first direction represented by arrow 38 and in an opposite second direction indicated by arrow 40 as discussed in further detail below. The second body element 36 includes a first major surface generally designated 42 relative to usage. The first major surface 42 of the second body element 36 may include a screen generally designated 44 constructed in at least a portion generally designated 46 of the first major surface 42. The second body element 36 may also include a second keypad arrangement generally designated 48 in at least another portion generally designated 50 of the first major surface 42. As illustrated in FIG. 2B, the second body element 36 is shown slid in the direction of arrow 38 with respect to the main body element 34 to a second or open operative position to reveal and expose a first keypad arrangement generally designated 52 carried in at least a portion 54 of a first major surface 56 relative to usage of the first main body element 34. As can be seen, the first keypad arrangement 52 is covered by the second body element 36 and not accessible by a user when the mobile telephone 32 is in its first operative position. In its second operative position as illustrated in FIG. 2B, the first keypad arrangement 52 is available as a user interface to operate the mobile telephone and any associated functions such as PDA functions in a manner well known to those skilled in the art and by the consuming public. FIG. 2C shows the mobile telephone 32 of FIG. 2A in an open or third operative position wherein the second body element 36 is slid in the direction shown by arrow 40 to reveal and expose a third keypad arrangement generally designated 58 constructed in the first major surface 56 of the main body element 34 in a portion 60 at the end 62 opposite the portion 54 of the main body element carrying the first keypad arrangement 52. The third keypad arrangement 56 is usable as a further user interface to operate additional features and function of the mobile telephone 32. For example, as illustrated in FIG. 2D, the mobile telephone 32 in its open or third operative position may reveal a camera imaging lens generally designated 64 carried in a second major surface 66 disposed opposite the first major surface 42 of the second body element 36. A user may aim the camera imaging lens 64 in the direction of the object or person whose image is to be captured and view the captured image on the screen 44 and operate one of the designated keys of the keypad arrangement 48 or 58 as required to activate the camera imaging function of the mobile telephone 32. The second body element 36 may be directly attached for slidable movement with respect to the first main body element 34 as shown in a schematic side view in FIG. 2E which represents the closed or first operative position. FIG. 2F is a schematic representation of the open or second operative position of the mobile telephone 32 wherein the second body element 36 is shown extended in one direction relative to the first main body element 34. FIG. 2G is a schematic representation of the mobile telephone 32 in its open or third operative position wherein the second body element 36 is shown extended in the opposite direction with respect to the second operative position. Alternately, the second body element 36 may be arranged for slidable movement with respect to the first main body element 34 by means of a sliding mechanism 68 sandwiched between the first main body element 34 and the second body element 36 to couple the first main body element and the second body element for relative movement with respect one another between the first, second and third operative positions as illustrated in FIGS. 2H, 2I and 2J respectively. The sliding mechanism may be arranged such that movement of one of the second body element or first main body element causes the other of the second body element and first main body element to move in the opposite direction of the element being moved by the user. Such a mechanism may be motor driven and mechanically couple the second body element and first main body element through a set of gears, belts or other mechanical coupling devices well known to those skilled in the art.

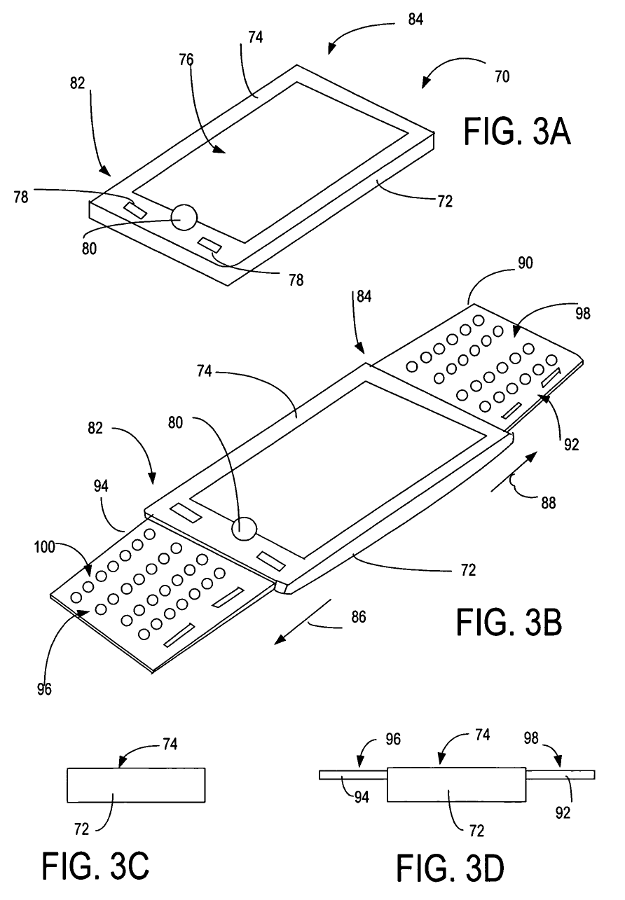

Turning now to FIGS. 3A-3D, a schematic perspective view of a second embodiment of the portable electronic device of the present invention shows a mobile telephone generally designated 70 in a closed or first operative position in FIGS. 3A and 3D. The mobile telephone 70 includes a first main body element 72 having a first major surface 74 relative to usage in an upwardly facing exposed configuration. A screen generally designated 76 is constructed in at least a portion of the first major surface 74. Keys 78 are constructed in at least a further portion of the first major surface 74 and which keys are operated by a user to carry out the intended function. The keys 78 are shown carried in one end region 82 although other locations and placements are contemplated in accordance with the particular design and function to be carried out. In addition, the mobile telephone 70 may include a user input device generally designated 80 which operates in a well known manner to control the direction of movement of a cursor for example on the display shown on the screen 76 or to carry out other intended functions as well known and understood to those skilled in the art. The mobile telephone 70 includes a second body element further comprising a first portion 90 and a second portion 94 nested within the first main body element 72 and unexposed and inaccessible with respect to usage in the closed or first operative position. In the second operative position as illustrated in FIG. 3B and FIG. 3D, the first portion 90 and second portion 94 extend from opposite end regions 82 and 84 respectively of the main body element 72. The mobile telephone 70 is reconfigured from its closed or first operative position to its open or second operative position the second body element first portion 90 is slid or extended away from the main body element in the direction as indicated by the arrow 88 and the second body element second portion 94 is slid or extended from the main body element in the opposite direction as shown by direction arrow 86. The second body element first portion 90 has a first major surface 92 relative to usage which may include an arrangement of keys 98 to carry out an intended function and which first major surface 92 is exposed and accessible by a user in the open or second operative position. The second body element second portion 94 also includes a first major surface 96 relative to usage and which first major surface is exposed and accessible by a user and may carry an arrangement of keys 100 to carry out an intended function. The major surfaces 92, 96 do not have to carry keys and may be alternatively configured and arranged as required as an intended user interface to carry out the intended function.

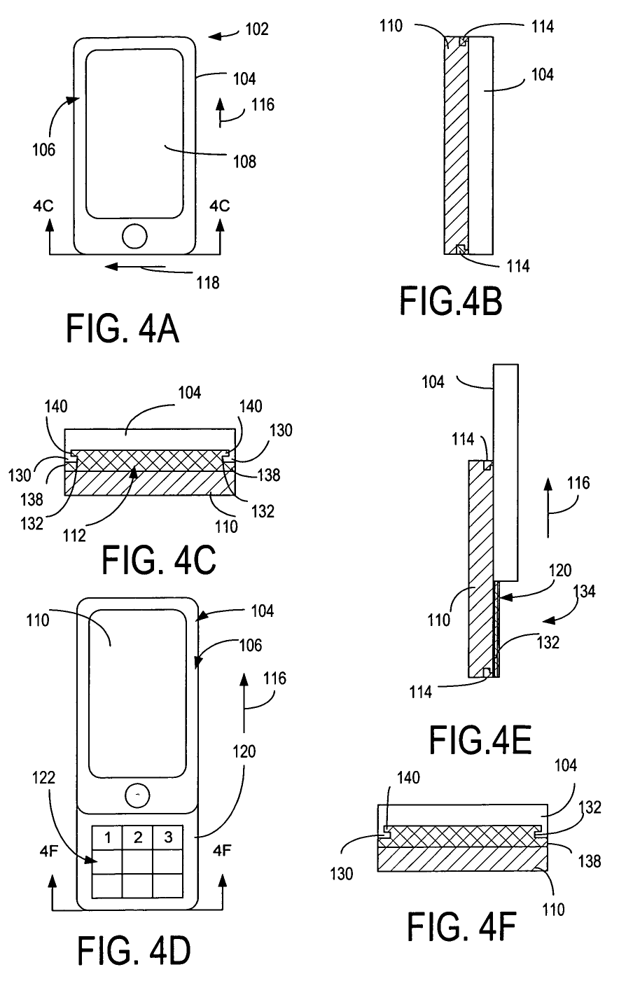

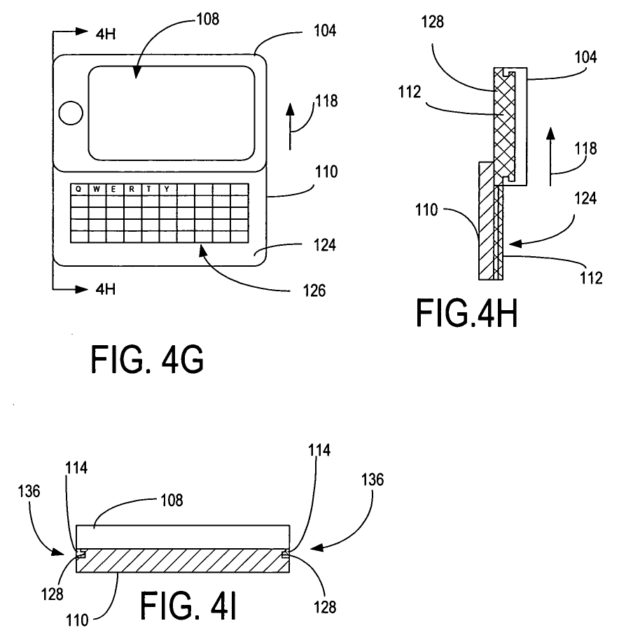

A third embodiment of the portable electronic device of the present invention is illustrated schematically in FIGS. 4A-4I which show a mobile telephone generally designated 102 having a sliding mechanism 112 sandwiched between the first main body element 110 and the second body element 104 and for mechanically coupling the body elements 110 and 104 to on another. The mobile telephone 102 has a closed or first operative position as illustrated in FIGS. 4A, 4B and 4C wherein the first main body element 110 and the sliding mechanism 112 and the second body element 104 are in an overlying stacked relationship with respect to one another. The second body element 104 has a first major surface 106 relative to usage and includes a screen 108 constructed in at least a portion of the first major surface 106. The second body element 104 is arranged for sliding engagement with the first main body element 110 in the direction as shown by the arrow 116 by means of oppositely disposed marginal legs 130, 130 extending lengthwise of the second body element 104. The legs 130, 130 are received in and co-act with respective oppositely disposed channels 132, 132 located lengthwise in the marginal areas of the sliding mechanism 112. The mobile telephone 102 has a vertically open or second operative position schematically illustrated in FIGS. 4D, 4E and 4F wherein the second body element 104 is slid or extended in a vertical direction as indicated by the arrow 116 with the lengthwise marginal legs 130 sliding lengthwise in the channels 132 of the sliding mechanism 112 as illustrated in FIG. 4E. The second body element 104 is slid vertically in the direction of arrow 116 to reveal a portion 134 of the sliding mechanism 112 and expose a major surface 120 of the sliding mechanism for use as a user interface. As illustrated in FIG. 4D, the major surface 120 may carry keys 122 arranged to carry out an intended function.

As illustrated schematically in FIGS. 4G, 4H and 4I, the second body element 104 and the sliding mechanism 112 are also arranged for slideable movement in a direction indicated by arrow 118 perpendicular to the lengthwise direction whereby the second body element 104 and the sliding mechanism 112 move together to uncover the first main body element 110 which exposes a first major surface 124 for access by a user in the horizontal open or third operative position. The first major surface 124 carries an arrangement of keys 126 configured to carry out an intended function and is illustrated for example as a QWERTRY keyboard in FIG. 4G. The slide mechanism 112 includes leg portions 114, 114 which are slidingly engaged for movement in slide tracks 128, 128 along the marginal opposite end regions 136, 136 of the slide mechanism 112.

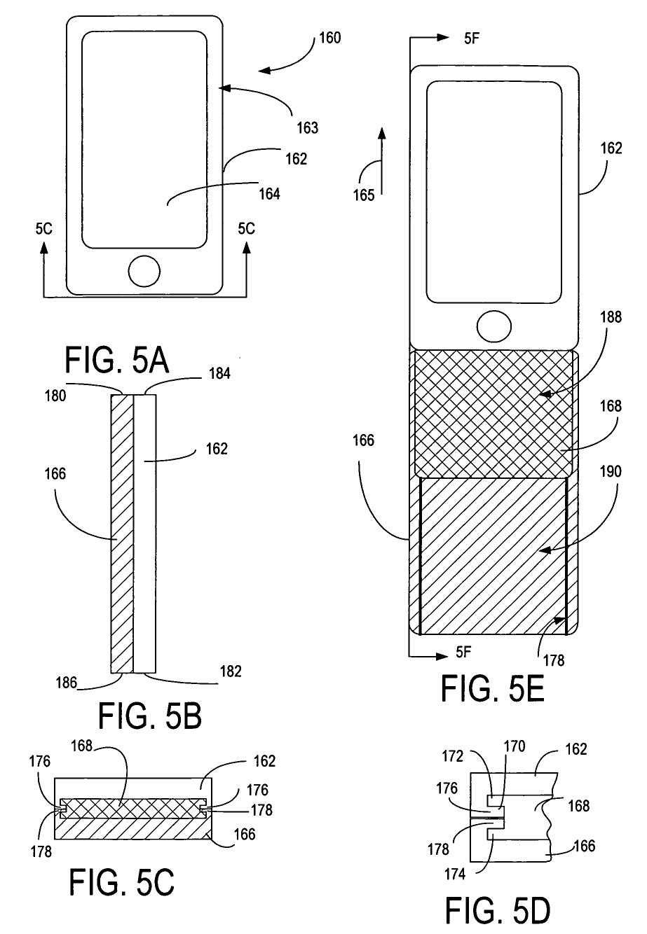

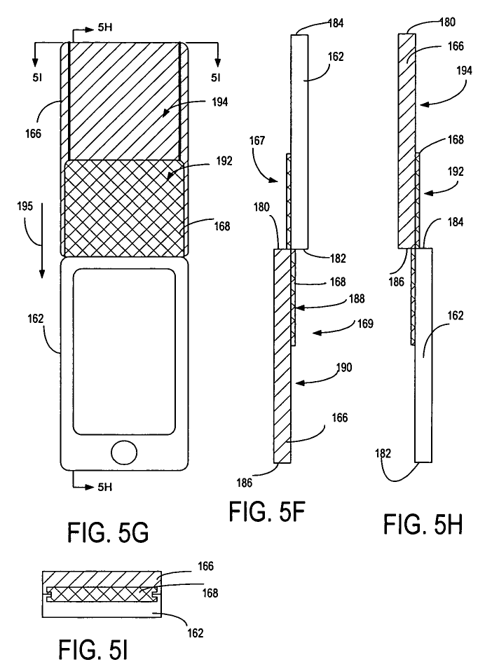

A fourth embodiment of the portable electronic device of the present invention is illustrated schematically in FIGS. 5A-5I wherein a mobile telephone 160 has a sliding mechanism generally designated 168 sandwiched between the first main body element 166 and the second body element 162. The second body element 162 has a major surface 163 relative to usage and may carry a screen 164. As illustrated in the side view shown in FIG. 5B, the first main body element 166 has an upper or top edge portion 180 and a lower or bottom edge 186. The second body element has an upper or top edge portion 184 and a lower or bottom edge portion 182. The main body element 166 and the second body element 162 are arranged for sliding engagement with respect to one another by means of a sliding mechanism 168 in the form of a plate sandwiched between the two elements. Oppositely disposed legs 176, 176 formed in the second body element are received in a lengthwise channel 170 formed by oppositely disposed tabs 172 and 174 extending from the ends of the sliding mechanism 168 as illustrated in the fragmentary view shown in FIG. 5D. The main body element 166 is likewise mechanically coupled to the sliding mechanism 168 by means of oppositely disposed legs 178, 178 received in the lengthwise channel 170 of the sliding mechanism 168 as illustrated in the fragmentary view shown in FIG. 5D. It will be seen that such an arrangement allows relative lengthwise movement between the main body element 166, the sliding plate mechanism 168 and the second body element 162. As illustrated in FIGS. 5E and 5F, the second body element 162 is slid or extended in a first vertical lengthwise direction as indicated by the direction arrow 165 relative to the main body element 166 and the sliding mechanism 168 and which sliding movement of the second body element 162 also causes the sliding mechanism 168 to move in the direction indicated by arrow 165 to the first vertically open operative position. In the first vertically open operative position, the lower edge 182 of the second body element is in approximately alignment with the upper edge 180 of the first main body element wherein approximately 50% of the upper portion 167 of the sliding mechanism 168 supports the second body element 162. The other half portion 169 of the sliding mechanism 168 supports the first main body element 166. The sliding mechanism includes a first major surface portion relative to usage generally designated 188 and which portion is revealed or exposed when the second body element is extended fully in the direction shown by the arrow 165 with respect to the first main body element 166. The first surface portion 188 may provide a user interface area and carry keys arranged as keypad or other desirable user input device to carry out an intended function. Also in the fully open vertical operative position, a first surface portion 190 of the first main body element 166 is revealed and accessible to a user. The first major surface 190 may function as a further user interface area and carry a keypad or other desired user input device in accordance with the intended function. The second body element 162 may also be moved in an opposite direction with respect to the first main body element 166 and the sliding mechanism 168 as indicated by the direction arrow 195 to a second vertical open operative position as illustrated in FIG. 5G. In the second vertically open operative position, a second surface portion 192 of the sliding mechanism 168 is revealed and may be arranged as a further user interface and include a desired user input device to carry out an intended function of the mobile telephone 160. Also in the second vertically open operative position, a second surface portion 194 of the main body element 166 is revealed and accessible to a user and likewise may carry a further user interface or user input device to carry out the intended function. Accordingly, the embodiment illustrated in FIGS. 5A-5H provides for at least four different user interface areas in the mobile telephone 160.

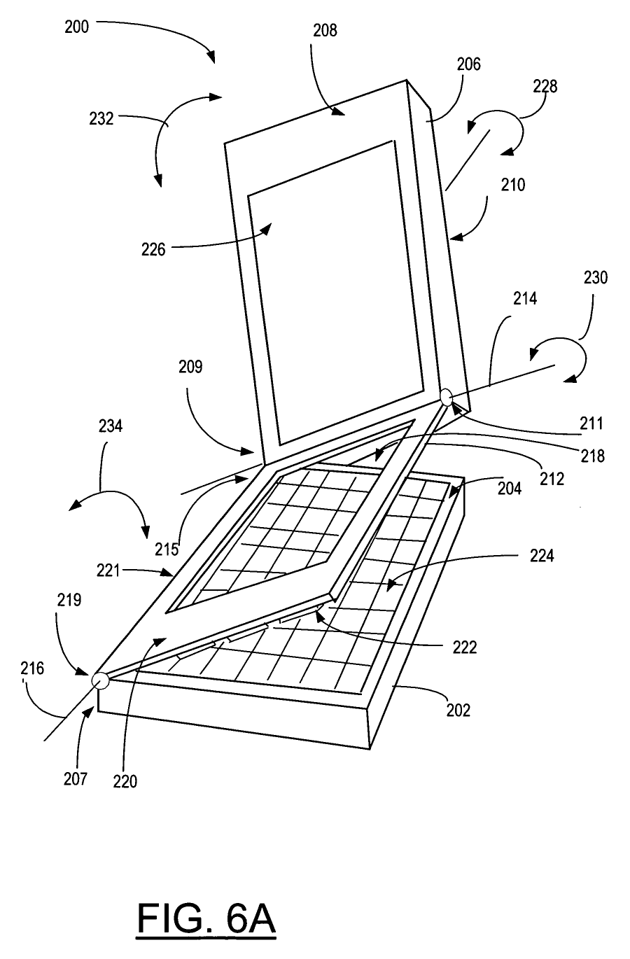

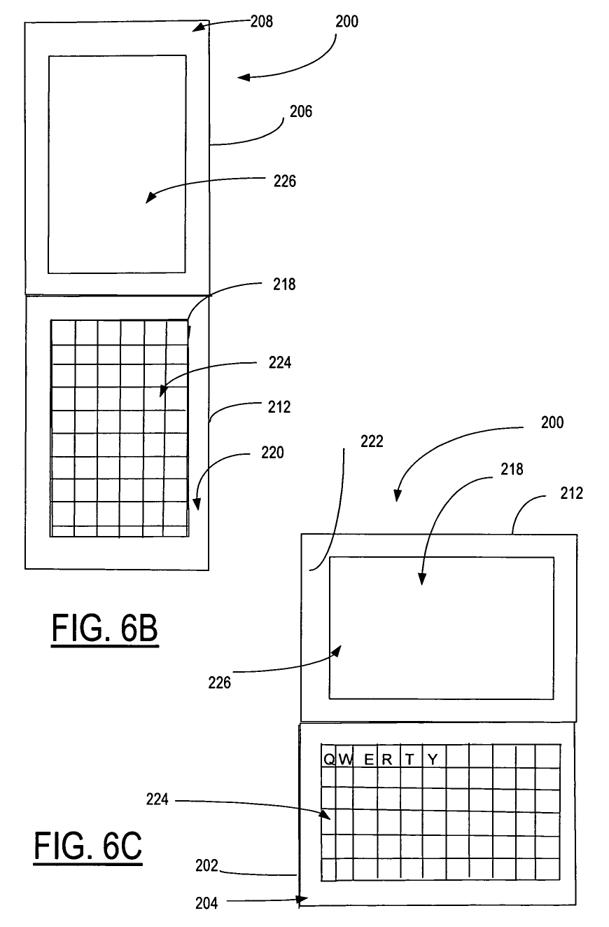

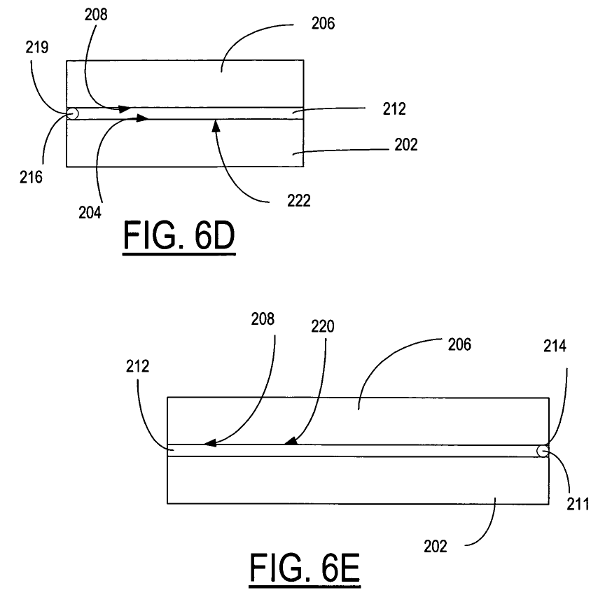

A fifth embodiment of the portable electronic device of the present invention is illustrated schematically in FIGS. 6A-6E which show a mobile telephone generally designated 200 having a foldable hinge frame 212 sandwiched between a first main body element 202 and a second body element 206. The second body element 206 is arranged for relative movement with respect to the first main body element 202 between a first or closed operative position as illustrated schematically by end and side views in FIGS. 6D and 6E respectively, and a vertical open operative position as shown in the top plan view in FIG. 6B and a third or horizontal open operative position as illustrated in the top plan view in FIG. 6C. The first main body element 202 has a first major surface 204 relative to usage and may carry an arrangement of keys forming a keypad generally designated 224 to carry out an intended function. The second body element 206 includes a first major surface 208 and an oppositely disposed second major surface 210. A screen 226 may be constructed in a portion of the surface 208. The second body element 206 is hingedly connected to the folding hinge frame 212 by means of a hinge 211 along the first hinge axis 214 passing through the intersection of one end 209 of the second body element 206 and one end 215 of the hinge frame 212. The second body element 206 is arranged for rotation about the hinge axis 214 in a direction indicated by the rotation direction arrow 230 as the second body element 206 is moved as indicated by the arrow 232 toward and away from the hinge frame first major surface 220. The first main body element 202 is hingedly connected to the foldable hinge frame 212 by means of a hinge 219 formed between the intersection of one side 221 of the hinge frame 212 and one side 207 of the first main body element 202. The first main body element 202 is arranged for rotation about the hinge axis 216 as indicated by the rotation direction arrow 228 when the hinge frame 212 is moved toward and away from the first major surface 204 of the first main body element 202 as indicated by the direction arrow 234. As illustrated in FIGS. 6D and 6E, in the closed position the major surface 208 of the second body element 206 is rotated about the axis 214 into a facing face-to-face relationship with the surface 220 of the hinge frame 212. The hinge frame 212 is rotated about the axis 216 in the direction of rotation arrow 228 such that the surface 222 of the hinge frame is in a face-to-face orientation with respect to the first major surface 204 of the first main body element 202. When the second body element 206 is rotated about the axis 214 to the vertical operative position as illustrated in FIG. 6B the major surface 208 of the second body element 206 lies in substantially the same plane as the major surface 220 of the hinge frame 212 and the keys 224 are accessible by a user through a window 218 defined in the hinge frame. When the second body element 206 and the hinge frame 212 are rotated together about the axis 216 to the horizontal operative position as illustrated in FIG. 6C the major surface 222 of the hinge frame 212 lies substantially in the same plane as the major surface 204 of the first main body element 202. The screen 226 is viewable through the window 218 in the hinge frame 212. The keys forming the keypad arrangement 224 are arranged to carry out the intended function and may be for example a QEWTRY keyboard. Further, the device includes appropriate electronics to orient the display shown on the screen 226 from a vertical to horizontal orientation as required depending on the operative position of the mobile telephone 200.

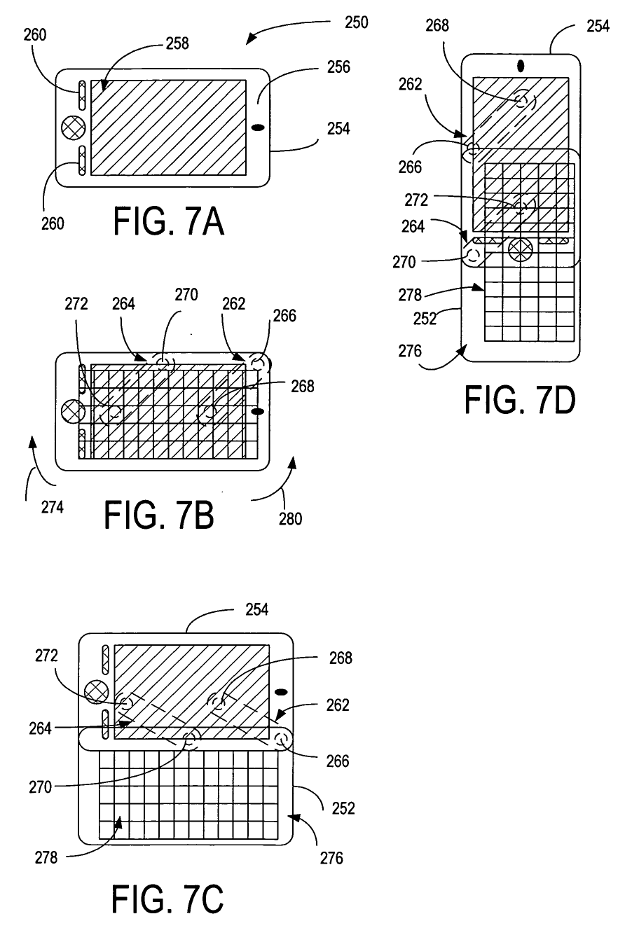

A sixth embodiment of the present invention is illustrated in FIGS. 7A-7D which show a mobile telephone generally designated 250 having swivel arms 262, 264 sandwiched between a first main body element 252 and a second body element 254 for mechanically coupling the first main body element to the second body element. The second body element 254 includes a first major surface 256. A screen 258 is constructed in at least a portion of the surface 256. Keys 260, 260 are also provided in another portion of the surface 256 for use in operating and carrying out the intended functions of the mobile telephone. In the first operative closed position as illustrated in FIGS. 7A and 7B, the second body element is in an overlying stacked relationship with the first main body element 252 such that the first major surface 256 of the second body element 254 is exposed and accessible by a user and the first major surface 276 of the first main body element 252 is covered by the second body element. The second body element 254 is moved from the first or closed operative position to a second or horizontal operative position as illustrated in FIG. 7C by moving or swiveling the second body element in a direction indicated by the arrow 274. The second body element 254 follows along a curved path and retains its orientation relative to the closed operative position as illustrated in FIG. 7A. The second body element 254 is in a top-bottom configuration with respect to the first main body element 252 in the second horizontal operative position as illustrated in FIG. 7C. An arrangement of keys forming a keypad 278 is constructed in the major surface 276 of the first main body element 252 and which keys are exposed and accessible to a user when the second body element is swiveled to its open horizontal position. The second body element 254 may be moved or swiveled with respect to the first main body element 252 and follow along a curved path indicated by the direction arrow 280 to a third or vertical open operative position as illustrated in FIG. 7D. A portion of the key arrangement 278 is exposed for access and operation by a user in the vertical open operative position. The pivot arms 262 and 264 may be used to carry power and data connections between the first main body element 252 and the second body element 254. Alternately, the data connection may be made via an optical link established and constructed between the first main body element 252 and the second body element 254.

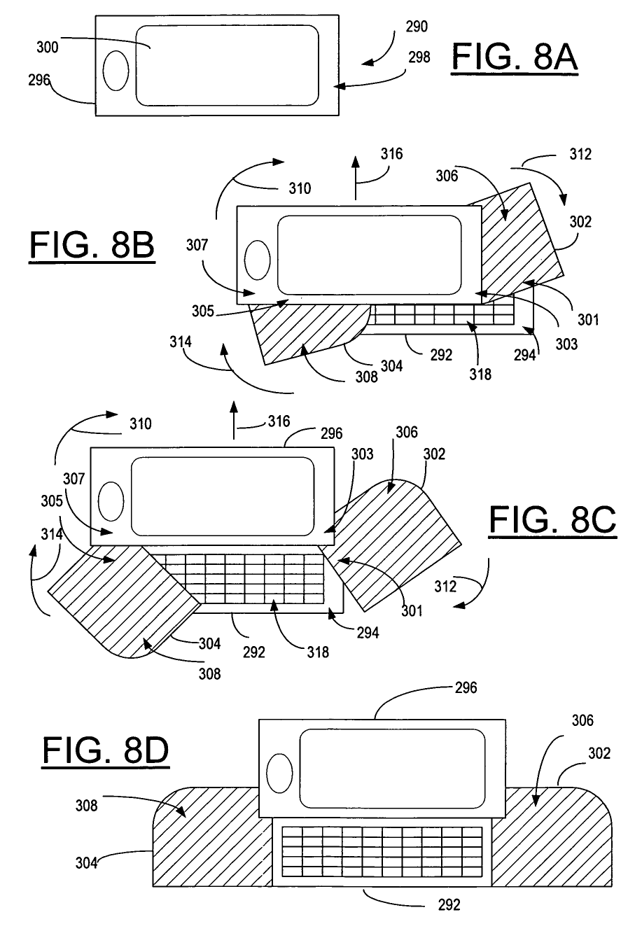

Turning now to FIGS. 8A-8D, a sixth embodiment of the present invention is illustrated schematically therein showing a mobile telephone generally designated 290 wherein a pair of swivel plates 302, 304 are sandwiched between the first main body element 292 and a second body element 296 for mechanically coupling the first main body element to the second body element. The swivel plate 302 is pivotally connected at the pivot point 301 to the first main body element 292. The swivel plate 302 is pivotally connected to the second body element 296 at the pivot point 303. In a similar manner, the swivel plate 304 is coupled to the first main body element 292 at the pivot point 305 and coupled to the second body element 296 at the pivot point 307. It can be seen that the connection arrangement between the second body element 296, swivel plates 302 and 304 and the first main body element 292 form a parallelogram such that movement of the second body element 296 along the arcuate path indicated by the direction arrow 310 causes the swivel plate 302 to follow along the arcuate path as indicated by the direction arrow 312 and the swivel plate 304 to follow an arcuate path as indicated by the direction arrow 314 as the second body element 296 moves in the same plane maintaining its orientation as in the closed position illustrated in FIG. 8A to the open horizontal operative position as illustrated in FIG. 8D. The swivel plates 302 and 304 move with the second body element 296 until the mobile telephone is in the horizontal operative position. The second body element 296 includes a major surface 298 which may carry a screen 300. The first main body element 292 includes a first major surface 294 relative to usage and may carry an arrangement of keys arranged to carryout the intended function and may be a keyboard for example, a QWERTY keyboard. The swivel plate 302 includes a major surface 306 relative to usage and provides an area for a user interface such as a keypad arrangement or other user input device. The swivel plate 304 also includes a major surface 308 relative to usage and likewise may carry an arrangement of keys or other user input device. Power and data connections between the main body element 292, swivel plates 302 and 304 and the second body element 296 may be carried via the pivot connections. Alternately, the data connection may be via an optical link between the main body element 292, swivel plates 302 and 304 and the second body element 296.

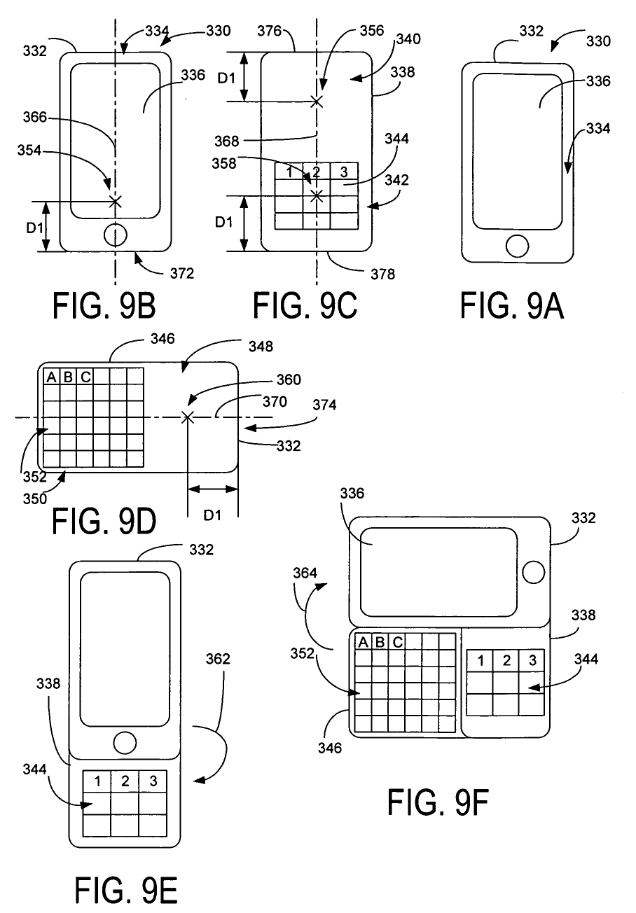

An eighth embodiment of the portable electronic device of the present invention is illustrated schematically in FIGS. 9A-9F and show a mobile telephone 330 having a swivel arm body 338 sandwiched between a first main body element 346 and a second body element 332 such that the swivel arm body 338 mechanically couples the main body element 346 to the second body element 332. The mobile telephone 330 has a first operative position as illustrated in FIG. 9A wherein the second body element 332 and the swivel arm body 338 and the main body element 346 are in an overlying stacked relationship with one another and the second body element major surface 334 is exposed and accessible by a user and the first main body element major face surface 348 and the swivel arm body major face surface 340 are covered. The second body element 332 is pivotally coupled at the pivot point 354 to the swivel arm body 338 at the pivot point 356. The swivel arm body 338 is pivotally coupled at the pivot point 358 to the main body element 346 at the pivot point 360. The second body element pivot point 354 lies on a lengthwise center axis 366 and is spaced a distance D1 from the edge 372. The pivot point 360 of the main body element lies on a lengthwise center axis 370 and is spaced a distance D1 from the edge 374. The pivot points 356 and 358 lie on a lengthwise center axis 368. The pivot point 356 is spaced a distance D1 from the edge 376 and the pivot point 358 is spaced a distance D1 from the edge 378. A user interface 342 is defined in at least a portion of the major surface 340 of the swivel arm body and may carry an arrangement of keys 344 to carryout an intended function. A user interface 350 is defined in at least a portion of the major surface 348 of the main body element 346 and may carry an arrangement of keys 352 to carryout an intended function. The mobile telephone 330 has a second or vertically open operative position as illustrated in FIG. 9E wherein the swivel arm body 338 and main body element 346 are rotated about the second body element 332 is pivot point 354 and the cooperating pivot point 356 along an arcuate path as indicated by the direction arrow 362 to expose the keypad 334 for access and use by a user. The swivel arm body 338 is in an overlying stacked relationship with the main body element 346 in the vertical operative position as shown in FIG. 9E. The mobile telephone 330 has a third or horizontal operative position as illustrated in FIG. 9F wherein the main body element 346 is rotated about the pivot point 360 and the cooperating pivot point 358 of the swivel arm body 338 along an arcuate path as indicated by direction arrow 364 to expose the keypad arrangement 352 for access and use by a user. The second body element 332 is rotated about the pivot point 354 and cooperating pivot point 356 of the swivel body 338 along an arcuate path as indicated by the direction arrow 364 whereby the orientation of the screen 336 is in a horizontal orientation. Power and data connections are made between the main body element 346, swivel arm body 338 and second body element 332 via the pivot point connections. Further, the keys of the keypad arrangement 352 may be arranged to carry out an intended function such as for example a QWERTY keyboard.

It is to be understood that the above-described arrangements are only illustrative of the application of the principles of the present invention and are not to be construed as limitations of the invention. Numerous modifications and alternative arrangements may be devised by those skilled in the art without departing from the scope of the invention and the appended claims are intended to cover such modifications and arrangements. Further, the invention contemplates all embodiments that may be inferred directly or indirectly from the disclosure and drawings whether or not expressly stated and claimed.

What is claimed is:

1. A device, comprising:
a first main body element having a first major surface relative to usage;
a second body element having a first major surface relative to usage;
an arm mechanism sandwiched between said first main body element and said second body element and arranged to mechanically couple said first main body element to said second body element for relative movement with respect to one another, wherein said first main body element is arranged for movement in a first plane and said second body element is arranged for movement in a second plane parallel with said first plane, to configure said first main body element and said second body element relative to one another in a number of different predetermined fixed orientations, each of said predetermined fixed orientations defining a corresponding different operative position of the device.

2. The device as defined in claim 1, further comprising:
a first operative position wherein said first main body element and said second body element are in an overlying stacked relationship with one another and said second body element first major surface is exposed and accessible by a user and said first main body element first major surface is covered by said second body element;
a second operative position wherein said second body element moves relative to said first main body element along a first arcuate path in a first direction from its overlying stacked relationship with said first main body element to a fully open orientation to uncover said first main body element first major surface for access by a user; and
a third operative position wherein said second body element moves relative to said first main body element along a second arcuate path in a second direction opposite said direction from its overlying stacked relationship with said first main body element to a lengthwise extended orientation to uncover a portion of said first main body element first major surface for access by a user.

3. The device as defined in claim 1 wherein a user interface is constructed in said first main body element first major surface.

4. The device as defined in claim 3 wherein the user interface comprises an arrangement of keys.

5. The device as defined in claim 4 wherein said arrangement of keys is a QWERTY keyboard.

6. The device as defined in claim 3 wherein the user interface is a user input device.

7. The device as defined in claim 1 wherein a display is constructed in said second body element first major surface.

8. The device as defined claim 1 wherein said arm mechanism further comprises a pair of arms sandwiched between said first main body element and said second body element.

9. The device as defined claim 8 wherein said arm mechanism further comprises a pair of swivel arms sandwiched between said first main body element and said second body element.

10. The device as defined in claim 1, wherein said device is a mobile telephone.

11. A device, comprising:
a first main body element having a first major surface relative to usage;
a second body element having a first major surface relative to usage;
means for mechanically coupling said first main body element to said second body element, wherein said second body element is arranged for relative movement with respect to said first main body element to configure said first main body element and said second body element in a number of different predetermined fixed orientations, each of said predetermined fixed orientations defining a corresponding different operative position.
